(19) United States
(12) Patent Application Publication
(10) Pub. No.: US 2014/0174811 A1
(43) Pub. Date: Jun. 26, 2014

(54) PRINTED CIRCUIT BOARD AND MANUFACTURING METHOD THEREOF

(71) Applicant: SAMSUNG ELECTRO-MECHANICS CO., LTD., Suwon (KR)

(72) Inventor: Young Soon KIM, Yeongi-gun (KR)

(73) Assignee: SAMSUNG ELECTRO-MECHANICS CO., LTD., Suwon (KR)

(21) Appl. No.: 14/070,072

(22) Filed: Nov. 1, 2013

(30) Foreign Application Priority Data
Dec. 21, 2012 (KR) 10-2012-0150771

(51) Int. Cl. H05K 3/40; H05K 1/11

(52) U.S. Cl. CPC H05K 3/4038; H05K 1/11
USPC 174/267; 29/852

(57) ABSTRACT

Disclosed herein are a printed circuit board and a manufacturing method thereof. The manufacturing method of the printed circuit board according to an exemplary embodiment of the present invention includes forming an insulating layer for a circuit pattern protection on a base substrate having a predetermined circuit pattern on at least one surface thereof; removing a part of the insulating layer to form an opened region having a predetermined pattern; applying copper particles onto the insulating layer including the opened region and then irradiating laser on a portion corresponding to the opened region; and fusing the copper particles applied onto the opened region by the laser irradiation to one another to form a copper post on the opened region.

### CROSS REFERENCE(S) TO RELATED APPLICATIONS

This application claims the benefit under 35 U.S.C. Section 119 of Korean Patent Application Serial No. 10-2012-0150771, entitled “Printed Circuit Board and Manufacturing Method Thereof” filed on Dec. 21, 2012, which is hereby incorporated by reference in its entirety into this application.

### BACKGROUND OF THE INVENTION

1. Technical Field

The present invention relates to a printed circuit board (PCB) and a manufacturing method thereof, and more particularly, to a printed circuit board having copper posts with approximately uniform heights formed on a substrate and a manufacturing method thereof.

2. Description of the Related Art

As an input/output (I/O) of a flip chip product increases, a bump of a printed circuit board (PCB) side also needs to have a fine pitch. Currently, in a case of a solder type bump generally used, an application of the bump having the fine pitch has confronted with a critical situation due to a change in volume thereof. In addition, as the bump has the fine pitch, a distance between a chip and the PCB serves as an important factor for a flow of a capillary underfill material which is applied for reliability. As such, as the bump has the fine pitch, the flow becomes difficult. In order to solve this, a bump structure having an increased height is demanded.

Generally, in order to solve the above-mentioned problem, a method forming a copper post using a copper electroplating instead of forming the solder bump is applied. At the time of applying the above-mentioned copper post forming method, an important parameter is flatness. That is, in the case in which the bumps on the PCB interconnected with the chip do not have the same height, a non-invasive defect at the time of interconnecting the PCB with the chip as well as a defect such as a crack by pressure applied at the time of attaching the chip may be generated in the chip. Therefore, at the time of forming the copper post, a technology forming the copper post enabling the copper post to have a uniform height is needed.

Generally, at the time of forming the copper post by electroplating as described above, drastic deviation between heights of the copper posts is generated. In addition, due to the above-mentioned height deviation, at the time of interconnecting the PCB with the chip, the crack is generated in the chip, such that product defect is caused.

### RELATED ART DOCUMENT

### Patent Document

(Patent Document 1) Korean Patent Laid-Open Publication No. 10-2001-0106196

### SUMMARY OF THE INVENTION

An object of the present invention is to provide a printed circuit board (PCB) having copper posts having approximately uniform heights formed on a substrate by applying fine copper particle on an opened region of an insulating layer on a substrate of the PCB and then irradiating laser thereon and a manufacturing method thereof.

According to an exemplary embodiment of the present invention, there is provided a printed circuit board, including: a base substrate having a predetermined circuit pattern on at least one surface thereof; an insulating layer formed on the base substrate and protecting the circuit pattern; and a bump formed on the base substrate and electrically connecting electronic components mounted on the base substrate to the circuit pattern, wherein the bump has an overall appearance of a vertical post shape and is formed so that a part of a body thereof is buried in the insulating layer.

A connection pad for a conductor bonding in order to smoothly bond between the base substrate and the bump may be formed between the base substrate and the bump.

According to another exemplary embodiment of the present invention, there is provided a manufacturing method of a printed circuit board, the method including: forming an insulating layer for a circuit pattern protection on a base substrate having a predetermined circuit pattern on at least one surface thereof; removing a part of the insulating layer to form an opened region having a predetermined pattern; applying copper particles onto the insulating layer including the opened region and then irradiating laser on a portion corresponding to the opened region; and fusing the copper particles applied onto the opened region by the laser irradiation to one another to form a copper post on the opened region.

The method may further include forming a connection pad for a conductor bonding at a predetermined portion of the base substrate before the forming of the insulating layer on the base substrate.

The applying of the copper particles onto the insulating layer including the opened region may be performed by using a screen printing method or an inkjet method.

As the copper particle, a copper particle having a diameter of 2 μm may be used.

The method may further include, after the forming of the copper post, cleaning a surface of the base substrate to remove residual copper particles which do not react on the laser irradiation.

The insulating layer may be made of a solder resist or an epoxy resin.

### BRIEF DESCRIPTION OF THE DRAWINGS

FIG. 1 is a view showing a structure of a printed circuit board according to an exemplary embodiment of the present invention;

FIG. 2 is a flow chart showing processes of executing a manufacturing method of a printed circuit board according to an exemplary embodiment of the present invention; and

FIGS. 3A to 3D are views sequentially showing processes manufacturing the printed circuit board according to the manufacturing method of the printed circuit board according to the exemplary embodiment of the present invention.

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Through the present specification, unless explicitly described otherwise, “comprising” any components will be understood to imply the inclusion of other components but not the exclusion of any other components. The terms “unit”, “module”, “device” or the like means a unit processing at least one function or operation, which may be implemented by hardware, software, or combinations of the hardware and the software.

Hereinafter, embodiments of the present invention will be described in detail with reference to the accompanying drawings.

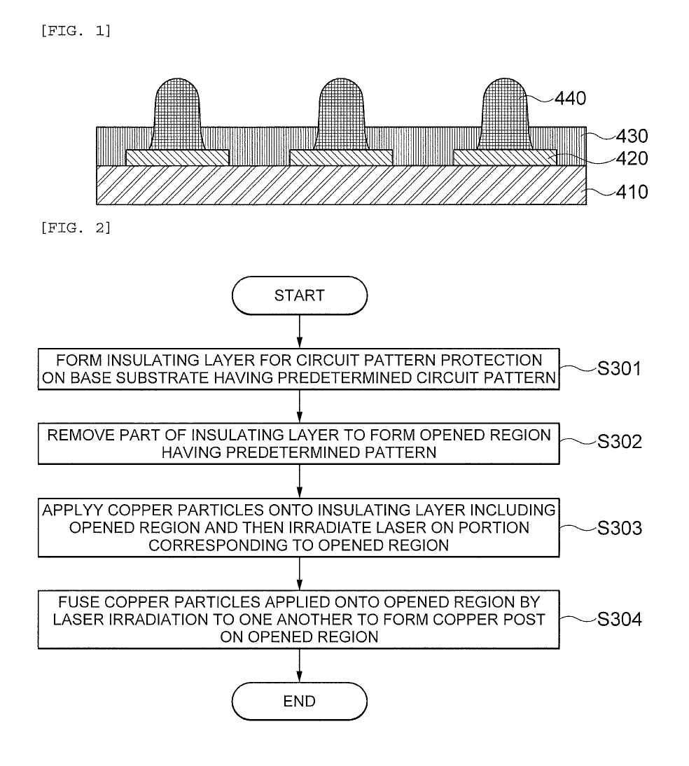

FIG. 1 is a view showing a structure of a printed circuit board according to an exemplary embodiment of the present invention.

Referring to FIG. 1, the printed circuit board according to the exemplary embodiment of the present invention includes a base substrate 410, an insulating layer 430, and bumps 440.

The base substrate 410 has a predetermined circuit pattern (not shown) on at least one surface thereof. The above-mentioned base substrate 410 may have a single-layer structure and may have a multi-layer structure.

The insulating layer 430 is formed on the base substrate 410 and serves to protect a circuit pattern formed on the base substrate 410. As a material of the above-mentioned insulating layer 430, a solder resist, an epoxy resin, or the like may be used.

The bump 440 is formed on the base substrate 410 and serves to electrically connect electronic components (for example, a semiconductor chip, an integrated chip (IC), and the like) mounted on the substrate to the circuit pattern.

Here, the bump 440 particularly has an overall appearance of a vertical post shape and is formed so that a part of a body thereof is buried in the insulating layer.

In addition, a connection pad 420 for a conductor bonding in order to smoothly bond between the base substrate 410 and the bump 440 may further be formed between the base substrate 410 and the bump 440.

Next, processes of manufacturing the printed circuit board having the structure as above described according the exemplary embodiment of the present invention will be described.

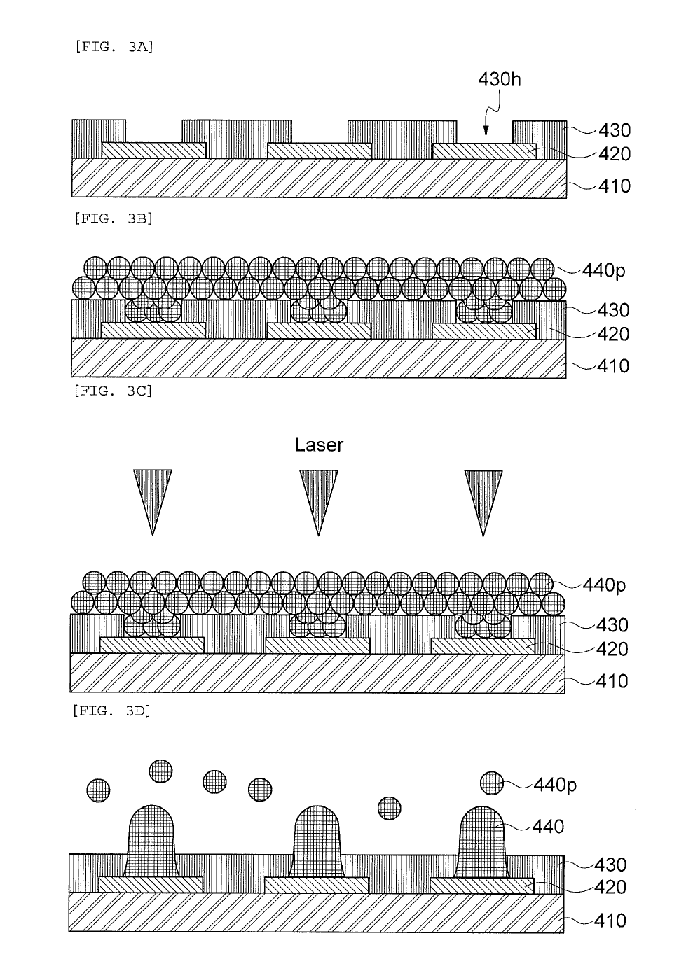

FIG. 2 is a flow chart showing processes of executing a manufacturing method of a printed circuit board according to an exemplary embodiment of the present invention and FIGS. 3A to 3D are views sequentially showing processes manufacturing the printed circuit board according to the manufacturing method of the printed circuit board according to the exemplary embodiment of the present invention.

Referring to FIGS. 2, and FIGS. 3A to 3D, according to the manufacturing method of the printed circuit board according to the exemplary embodiment of the present invention, an insulating layer 430 for a circuit pattern protection is formed on the base substrate 410 having a predetermined circuit pattern (not shown) on at least one surface thereof (S301). In this case, as a material of the above-mentioned insulating layer 430, a solder resist, an epoxy resin, or the like may be used.

Here, In addition, the manufacturing method of the printed circuit board according to the exemplary embodiment of the present invention may further include forming the connection pad 420 for the conductor bonding at a predetermined portion of the substrate 410 before forming the insulating layer 430 on the base substrate 410.

As described above, when the forming of the insulating layer is completed, an opened region 430h having a predetermined pattern is formed by removing a part of the insulating layer 430 (that is, a part of the insulating layer on the portion of the connection pad 420) (S302).

Thereafter, copper particles 440p are applied onto the insulating layer 430 including the opened region 430h and laser is then irradiated on a portion corresponding to the opened region 430h (S303). Here, in order to apply the copper particle 440p onto the insulating layer 430 including the opened region 430h, a screen printing method, an inkjet method, or the like may be used. In this case, as the copper particle 440p, the copper particle having a diameter of 2 μm may be used. In this case, as the laser, excimer laser or CO₂ laser may be used.

As described above, the laser is irradiated and the copper particles 440h applied onto the opened region are fused to one another by the laser irradiation, such that the copper post 440 (that is, the bump) is formed on the opened region 430h (S304). That is, the fine copper particles 440p are each supplied with energy by the laser irradiation to cause a surface thereof to be changed (that is, fused), such that they are fused to one another to form a mass. In addition, the above-mentioned mass forms the copper post 440. Here, the above-mentioned copper post 440 has an overall appearance of a vertical shape, wherein this is due to a strength distribution (a Gaussian distribution) of a laser energy wavelength. When the laser energy has the most ideal Gaussian distribution, the shape of the copper post 440 also forms a perfect vertical shape of bilateral symmetry based on a central axis.

As described above, when the forming of the copper post 440 is completed, the manufacturing method of the printed circuit board according to the exemplary embodiment of the present invention may further include cleaning a surface of the substrate (the insulating layer) to remove residual copper particles which do not react on the laser irradiation.

As described above, the printed circuit board and the manufacturing method thereof according to the exemplary embodiment of the present invention form the posts by the copper particle having a uniform particle size, thereby making it possible to significantly decrease height deviation of the posts. Therefore, the chip crack generated at the time of interconnecting the PCB with the chip due to the copper post having the height deviation formed by the existing electroplating may be prevented.

In addition, it is suppressed that an intermetallic compound layer is generated at a copper boundary surface according to the related art, thereby making it possible to solve a chronic problem at the time of using the solder bump.

According to the exemplary embodiment of the present invention as described above, the post is formed of copper particle having a uniform particle size, thereby making it possible to significantly decrease height deviation of the post. Therefore, the chip crack generated at the time of interconnecting the PCB with the chip due to the copper post having the height deviation formed by the existing electroplating may be prevented.

Although the preferred embodiments of the present invention have been disclosed, the present invention is not limited thereto, but those skilled in the art will appreciated that various modifications, additions and substitutions are possible, without departing from the scope and spirit of the invention as disclosed in the accompanying claims. Therefore, the true scope of the present invention should be construed by the following claims, and all of the technical spirit of the present invention within equivalent range thereof are included in scope of the present invention.

What is claimed is:

1. A printed circuit board, comprising:
a base substrate having a predetermined circuit pattern on at least one surface thereof;
an insulating layer formed on the base substrate and protecting the circuit pattern; and
a bump formed on the base substrate and electrically connecting electronic components mounted on the base substrate to the circuit pattern,
wherein the bump has an overall appearance of a vertical post shape and is formed so that a part of a body thereof is buried in the insulating layer.

2. The printed circuit board according to claim 1, wherein a connection pad for a conductor bonding in order to smoothly bond between the base substrate and the bump is formed between the base substrate and the bump.

3. A manufacturing method of a printed circuit board, the method comprising:
forming an insulating layer for a circuit pattern protection on a base substrate having a predetermined circuit pattern on at least one surface thereof;
removing a part of the insulating layer to form an opened region having a predetermined pattern;
applying copper particles onto the insulating layer including the opened region and then irradiating laser on a portion corresponding to the opened region; and
fusing the copper particles applied onto the opened region by the laser irradiation to one another to form a copper post on the opened region.

4. The method according to claim 3, further comprising forming a connection pad for a conductor bonding at a predetermined portion of the base substrate before the forming of the insulating layer on the base substrate.

5. The method according to claim 3, wherein the applying of the copper particles onto the insulating layer including the opened region is performed by using a screen printing method or an inkjet method.

6. The method according to claim 5, wherein as the copper particle, a copper particle having a diameter of 2 μm is used.

7. The method according to claim 3, further comprising, after the forming of the copper post, cleaning a surface of the base substrate to remove residual copper particles which do not react on the laser irradiation.

8. The method according to claim 3, wherein the insulating layer is made of a solder resist or an epoxy resin.

9. The method according to claim 3, wherein the laser is excimer laser or CO₂ laser.
